(19) United States
(12) Patent Application Publication
(10) Pub. No.: US 2007/0013070 A1
(43) Pub. Date: Jan. 18, 2007

(54) Semiconductor devices and methods of manufacture thereof

(76) Inventors: Mong Song Liang, Hsin-Chu (TW); Hun-Jan Tao, Hsin-Chu (TW); Jim Huang, Hsin-Chu (TW); Ling-Yen Yeh, Jhubei City (TW); Yu-Lien Huang, Jhubei City (TW)

Correspondence Address: SLATER & MATSIL, L.L.P., 17950 PRESTON ROAD, SUITE 1000, DALLAS, TX, 75252, US

(21) Appl. No.: 11/159,709

(22) Filed: Jun. 23, 2005

(51) Int. Cl. H01L 23/52

(52) U.S. Cl. 257/758

(57) ABSTRACT

Novel etch stop layers for semiconductor devices and methods of forming thereof are disclosed. In one embodiment, an etch stop layer comprises tensile or compressive stress. In another embodiments, etch stop layers are formed having a first thickness in a first region of a workpiece and at least one second thickness in a second region of a workpiece, wherein the at least one second thickness is different than the first thickness. The etch stop layer may be thicker over top surfaces than over sidewall surfaces. The etch stop layer may be thicker over widely-spaced feature regions and thinner over closely-spaced feature regions.

### TECHNICAL FIELD

The present invention relates generally to the manufacture of semiconductor devices, and more particularly to the formation of etch stop layers.

### BACKGROUND

Generally, semiconductor devices are fabricated by depositing a plurality of insulating, conductive, and semiconductive material layers over a substrate or workpiece, and patterning the various material layers to form integrated circuits and electrical devices or elements thereon. The conductive, semiconductive, and insulating material layers are patterned using lithography and etched to form integrated circuits (IC's).

Etch stop layers are often used in semiconductor manufacturing. An etch stop layer typically comprises a material that is resistant to etching by a particular chemical or etch process that will be used to etch a material layer that is deposited over the etch stop layer, for example. An etch process is typically used that is adapted to remove the material layer disposed over the etch stop layer, preferentially to the removal of the etch stop layer.

Etch stop layers allow for increased control in the etch process of the overlying material layer. Etch stop layers also protect underlying layers disposed beneath the etch stop layer during the etch process.

A problem that can occur in the formation of etch stop layers is that the etch stop layer may be too thick in some portions of a semiconductor device. In some applications, such as devices having embedded memory, for example, there may not be a common or unique thickness for an etch stop layer that is suitable for all regions of the semiconductor device. If the etch stop layer is too thick, then when the etch stop layer is opened using an etch process, a portion of the etch stop layer may remain present in undesired regions. When the patterned etch stop layer is later filled with a conductive material, electrical contact is not made to the underlying region, due to the presence of the portion of the etch stop layer left remaining, because the etch stop layer comprises an insulating material. The under-etching of the etch stop layer results in “open” regions, where electrical current does not flow, which causes device failures and decreases semiconductor device yields.

Thus, what are needed in the art are improved etch stop layers for use in semiconductor device manufacturing.

### SUMMARY OF THE INVENTION

These and other problems are generally solved or circumvented, and technical advantages are generally achieved, by preferred embodiments of the present invention, which comprise novel etch stop layers and methods of formation thereof. In one embodiment, an etch stop layer comprises a material having tensile or compressive stress. In another embodiment, an etch stop layer is thicker over top surfaces than on sidewall surfaces of the semiconductor device. In yet another embodiment, an etch stop layer is thicker over some regions of a workpiece than over other regions of a workpiece.

In accordance with a preferred embodiment of the present invention, a semiconductor device includes a workpiece having a first region and a second region, and an etch stop layer disposed over the workpiece. The etch stop layer comprises a first thickness in the first region and at least one second thickness in the second region, wherein the at least one second thickness is greater than the first thickness.

In accordance with another preferred embodiment of the present invention, a semiconductor device includes a workpiece, and an etch stop layer over the workpiece. The etch stop layer comprises a tensile stress of about 0.8 GPa or greater, or a compressive stress of about −1.0 GPa or less.

Advantages of embodiments of the present invention include providing an etch stop layer that is thicker in some regions and thinner in other regions, and/or has a high amount of stress. The yield of semiconductor devices may be increased by the use of embodiments of the present invention. The etch stop layer may be used to cause stress in the channel of an underlying transistor, in some embodiments.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a preferred embodiment of the present invention, wherein an etch stop layer comprises a material having tensile or compressive stress;

FIG. 2 shows a cross-sectional view of another preferred embodiment of the present invention, wherein an etch stop layer comprises a greater thickness on top surfaces than sidewall surfaces;

FIG. 3 shows an embodiment of the present invention, wherein features of the semiconductor device comprise gates of transistors, wherein the etch stop layer increases the stress of the channels of the transistors;

FIG. 4 shows another embodiment of the present invention, wherein an etch stop layer comprises a greater thickness in widely-spaced feature regions than in closely-spaced feature regions;

FIGS. 5 through 10 illustrate a semiconductor device at various stages of manufacturing in accordance with a preferred method of the present invention;

FIGS. 11 through 14 illustrate a semiconductor device at various stages of manufacturing in accordance with another preferred method of the present invention; and

FIG. 15 shows a cross-sectional view of yet another preferred embodiment of the present invention, where portions of the etch stop layer over the top surface of the workpiece have a reduced thickness.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

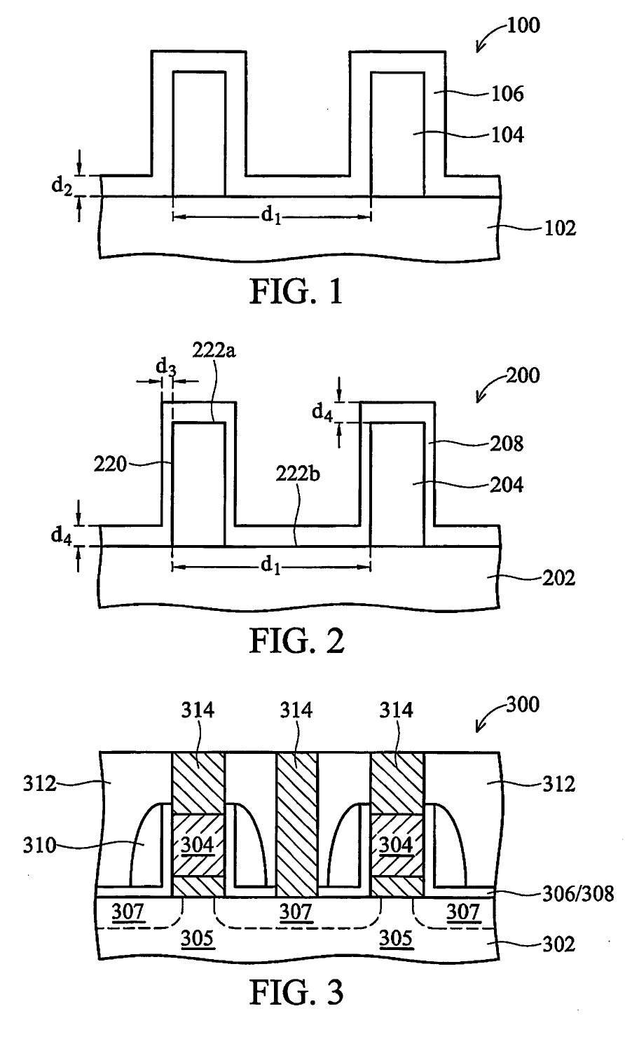

FIG. 1 shows a cross-sectional view of a preferred embodiment of the present invention, wherein an etch stop layer 106 comprises a material having tensile or compressive stress. To manufacture the novel semiconductor device 100, first, a workpiece 102 is provided. The workpiece 102 preferably comprises a semiconductor substrate comprising silicon or other semiconductor materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may also comprise a silicon-on-insulator (SOI) substrate, for example (not shown).

At least one feature 104 is formed over the workpiece 102. Two features 104 are shown in FIG. 1; however, one feature 104 may be formed, or three or more features 104 may be formed, as examples. The features 104 may comprise polysilicon or metal, for example, and may make electrical contact to active areas (not shown) of the workpiece 102, for example. The features 104 may comprise a gate of a transistor, disposed over a gate oxide (not shown), for example. The features 104 comprise a pitch d₁, wherein the pitch d₁ is the distance from one edge of a feature 104 to an edge of an adjacent feature 104, as shown. For example, the pitch includes the width of the feature 104 and the space between the feature 104 to an adjacent feature 104. The features 104 preferably comprise a pitch d₁ of about 300 nm or less, and more preferably comprise a pitch d₁ of about 100 nm to about 250 nm, as examples, although the features 104 may alternatively comprise a pitch d₁ comprising larger dimensions.

An etch stop layer 106 is formed over the features 104 and over the top surface of the workpiece 102, as shown. The etch stop layer 106 in this embodiment preferably comprises a thickness d₂ of about 100 nm or less, and more preferably comprises a thickness of about 10 nm to about 80 nm, in one embodiment, although alternatively, the thickness d₂ of the etch stop layer 106 may comprise other dimensions, for example.

The etch stop layer 106 preferably comprises SiN in one embodiment, although alternatively, the etch stop layer 106 may comprise other materials or multiple layers of materials, such as other nitride-containing materials, SiON, SiC, or carbon-doped oxide deposited by chemical vapor deposition (CVD), as example, although the etch stop layer 106 may alternatively comprise other materials.

In some embodiments, the etch stop layer 106 preferably comprises a material having a high internal stress. For example, in one embodiment, the etch stop layer 106 comprises a tensile stress of about 0.8 GPa or greater. The etch stop layer 106 may comprise a compressive stress of about −1.0 GPa or less, in another embodiment. The stress is introduced by the selection of the material of the etch stop layer 106 and/or the processes used to form the etch stop layer, for example.

For example, the etch stop layer 106 may be formed using a plasma enhanced CVD or other deposition process at a power of about 0 to 250 Watts, a pressure of about 2 to 10 Torr, a flow rate of about 5,000 to 35,000 standard cubic centimeters per minute (s.c.c.m.), at a temperature of about 300 to 600 degrees C. The etch stop layer 106 may be exposed to other processing or treatments after the deposition process, such as heating the workpiece 102 and the etch stop layer 106 at a temperature of about 300 to 900 degrees C. using a rapid thermal anneal or a furnace, ultraviolet (UV) curing the etch stop layer 106, or exposing the etch stop layer to an e-beam, as examples. Alternatively, other deposition processes, parameters, and post-deposition treatments may be used, for example.

To form the etch stop layer 106, the workpiece 102 may be placed in a deposition chamber, and a gas may be introduced during the deposition process, for example. The etch stop layer 106 deposition process may include using a gas comprising silane, NH₃, or N₂, as examples, although alternatively, other gases may be used.

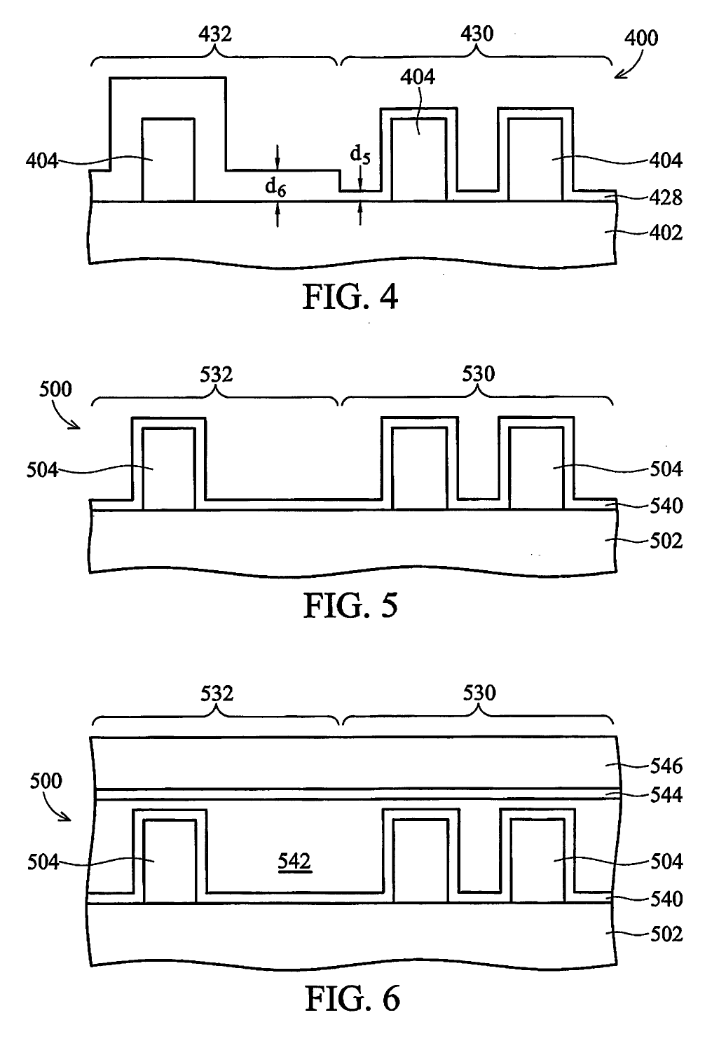

FIG. 2 shows a cross-sectional view of another preferred embodiment of the present invention, wherein an etch stop layer 208 comprises a greater thickness on top surfaces 222a and 222b than sidewall surfaces 220. Like numerals are used for the various elements that were used in FIG. 1. To avoid repetition, each reference number shown in FIG. 1 is not described again in detail herein. Rather, similar materials x02, x04, etc. are preferably used for the various material layers shown as were described for FIG. 1, where x=1 in FIG. 1 and x=2 in FIG. 2. As an example, the preferred and alternative materials and dimensions described for the features 104 in the description for FIG. 1 are preferably also used for the features 204 shown in FIG. 2.

The etch stop layer 208 shown in FIG. 2 preferably comprises similar materials and is deposited by similar methods as described for etch stop layer 106 in FIG. 1, for example. However, in this embodiment, preferably a material and deposition method is selected so that the etch stop layer 208 deposited comprises a first thickness d₃ and at least one second thickness d₄, wherein the at least one second thickness d₄ is different than the first thickness d₃, for example. The etch stop layer 208 comprises the first thickness d₃ over a first region and a second thickness d₄ in a second region, for example. In the embodiment shown, the first region comprises sidewalls 220 of the features 204, and the second region comprises top surfaces 222a of the features 204 and the top surfaces 222b of the workpiece 202, as shown. The at least one second thickness d₄ is preferably greater than the first thickness d₃, as shown.

The at least one second thickness d₄ may comprise a third thickness, for example, not shown in the drawings. In this embodiment, the etch stop layer 106 may comprise two or more thicknesses across the top surface of the workpiece 202, for example.

Preferably, the deposition process for the etch stop layer 208 has poor step coverage in this embodiment, to achieve the first thickness d₃ and the at least one second thickness d₄, for example. Preferably, the first thickness d₃ and the at least one second thickness d₄ of the etch stop layer 208 comprise about 100 nm or less, and more preferably comprises a thickness of about 10 nm to about 80 nm, as examples, although alternatively, the first thickness d₃ and the at least one second thickness d₄ may comprise other dimensions.

In one embodiment, the at least one second thickness d₄ is greater than the first thickness d₃ by about 20 nm or greater. The first thickness d₃ may be about 70% or less than the at least one second thickness d₄, for example. As another example, the ratio of the thickness on the sidewalls to the thickness on the top surface may comprise about 70% or less. In another embodiment, the first thickness d₃ is preferably about 50% or less than the at least one second thickness d₄, for example.

In one embodiment, the etch stop layer 208 may comprise a high amount of stress. The etch stop layer 208 may comprise a tensile stress of about 0.8 GPa or greater, for example. As another example, the etch stop layer 208 may comprise a compressive stress of about −1.0 GPa or less, as examples. The novel etch stop layer 208 may alternatively not comprise a high level of stress, in other embodiments, for example.

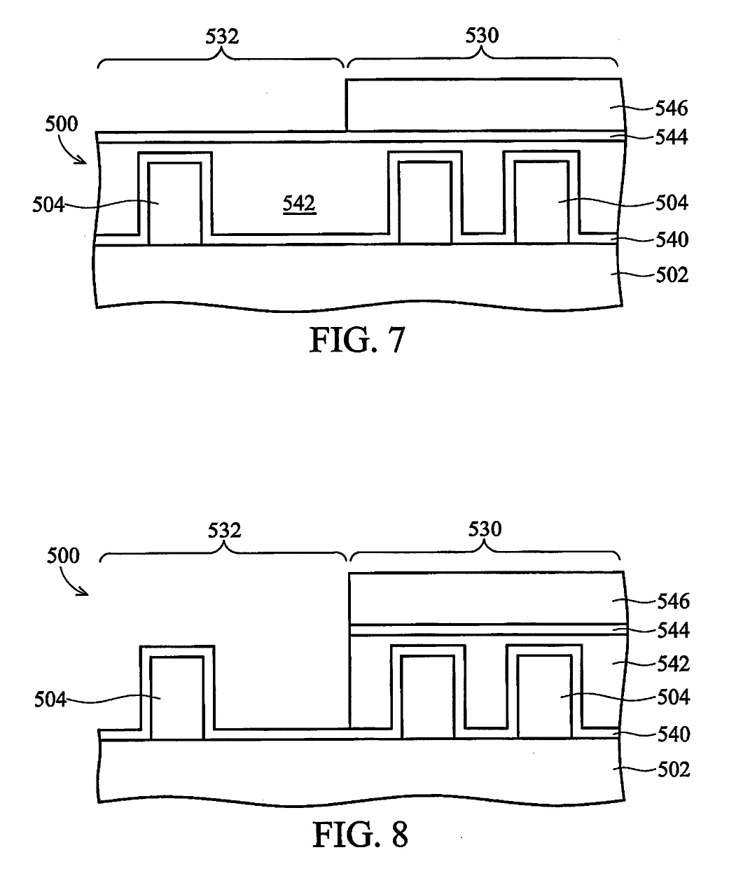

The manufacturing processes of the semiconductor devices 100 and 200 shown in FIGS. 1 and 2, respectively, are then continued to complete the manufacturing of the semiconductor devices 100 and 200. For example, as shown in FIG. 3, spacers 310 may be formed on sidewalls of the etch stop layer 306/308, and an insulating material 312 may be formed over the etch stop layer 306/308 and the spacers 310. The insulating material 312 may comprise silicon dioxide, silicon nitride, low dielectric constant (k) materials, combinations thereof, or other insulating materials, as examples. Conductive plugs comprising vias or contacts 314 may be formed in the insulating material 312 to make electrical contact to the features 304 and/or active areas 307 of the workpiece 302. The conductive plugs may comprise contacts 314 that make electrical connection to contact pads in overlying material layers, not shown, for example. Alternatively, the conductive plugs may comprise vias that make electrical connection to other elements or conductive lines in overlying material layers, also not shown. Again, like numerals are used in FIG. 3 as were used in the previous figures. The etch stop layer 306/308 may comprise a single thickness as described with reference to FIG. 1, or may comprise a dual thickness (not shown in FIG. 3; see FIG. 2) as described with reference to FIG. 2, for example.

To form the vias or contacts 314, typically, a photoresist (not shown) is deposited over the insulating material 312, and the photoresist is used as a mask while the insulating material 312 is patterned. The etch process for the insulating material 312 may be designed to stop when the etch stop layer 306/308 is reached, for example. Exposed portions of the etch stop layer 306/308 are then etched away, and the patterned insulating material 312 is filled with a conductive material such as metal or a semiconductive material such as polysilicon, as examples. Excess conductive material may then be removed from over the top surface of the insulating material 312 using a chemical mechanical polish (CMP) or etch process, for example.

In accordance with embodiments of the present invention wherein the etch stop layer 306/308 comprises a high amount of stress, advantageously, the etch stop layer 306/308 may induce stress in underlying material layers formed in or over the workpiece 302. As an example, the features 304 may comprise gates of transistors, wherein the transistors comprise source and drain regions 307 formed in the workpiece, with a channel region 305 being formed beneath each gate 304 (a gate oxide, not shown, also resides between the gate 304 and channel region 305) between the source and drain regions 307, as shown in FIG. 3. The etch stop layer 306/308 comprising a high amount of stress induces stress and/or increases the stress in the channel region 305, which may improve the performance of the transistor and the semiconductor device 300, for example.

In another embodiment, the spacers 310 preferably comprise the same material as the etch stop material 306/308, for example. In another embodiment, the spacers 310 and the etch stop material 306/308 preferably both comprise a nitride material.

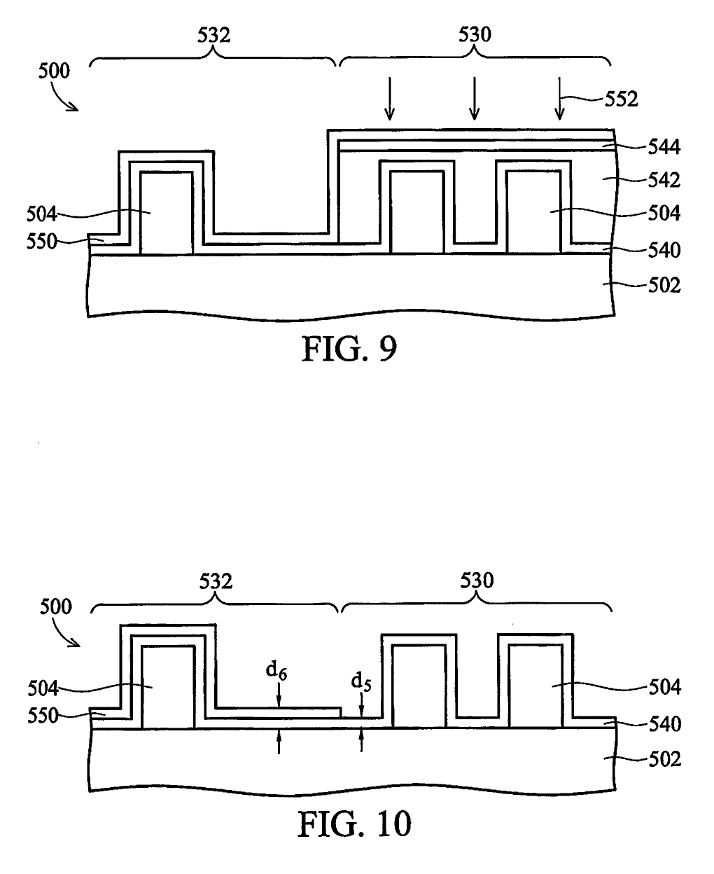

FIG. 4 shows another embodiment of the present invention, wherein an etch stop layer 428 comprises a greater thickness in widely-spaced feature regions 432 than in closely-spaced feature regions 430. Again, like numerals are used in FIG. 4 as were used in the previous figures, and each element is not described in detail again herein. The etch stop layer 428 preferably comprises the same materials and thicknesses as were described for etch stop layers 106, 208, 306, and 308, for example.

In this embodiment, the workpiece 402 includes at least one first region 430 and at least one second region 432. Only one first region 430 and second region 432 are shown in the figure; however, there may be a plurality of first regions 430 and second regions 432 on the semiconductor device 400, not shown. The first region 430 preferably comprises a region of closely-spaced features, and is also referred to herein as a close-spaced feature region. The second region 432 preferably comprises a region of widely-spaced features, and is also referred to herein as a widely-spaced feature region.

The closely-spaced feature region 430 may comprise features 404 that operate at a first speed, and the widely-spaced feature region 432 may comprise features 404 that operate at a second speed, the first speed being greater than the second speed, in one embodiment. In another embodiment, the closely-spaced feature region 430 preferably comprises features 404 comprising a plurality of memory devices, and the widely-spaced feature region 432 preferably comprises features 404 comprising a plurality of logic devices, in another embodiment. The widely-spaced feature region 432 may comprise support circuitry and circuits designed to access memory devices in the closely-spaced feature region 430, for example. The closely-spaced feature region 430 may comprise a plurality of memory cells, arranged in an array, for example, such as static random access memory (SRAM) cells or dynamic random access memory (DRAM) cells, although alternatively, the closely-spaced feature region 430 may comprise other types of memory cells.

Features 404 in the widely-spaced feature region 432 are preferably spaced apart from one another by a greater distance than features 404 in the closely-spaced feature region 430. For example, features 404 in the widely-spaced feature region 432 may be spaced apart from one another by about 2 to 5 times or more than features 404 in the closely-spaced feature region 430 are spaced apart from one another, as an example. Features 404 in the closely-spaced feature region 430 may comprise a minimum feature size of the semiconductor device 400, for example.

The etch stop layer 428 preferably comprises a first thickness d₅ in the first region 430 and at least one second thickness d₆ in the second region 432, wherein the at least one second thickness d₆ is preferably greater than the first thickness d₅. The first thickness d₅ and the at least one second thickness d₆ preferably comprise similar dimensions as were described for the first thickness d₃ and the at least one second thickness d₄, respectively, of FIG. 2, for example.

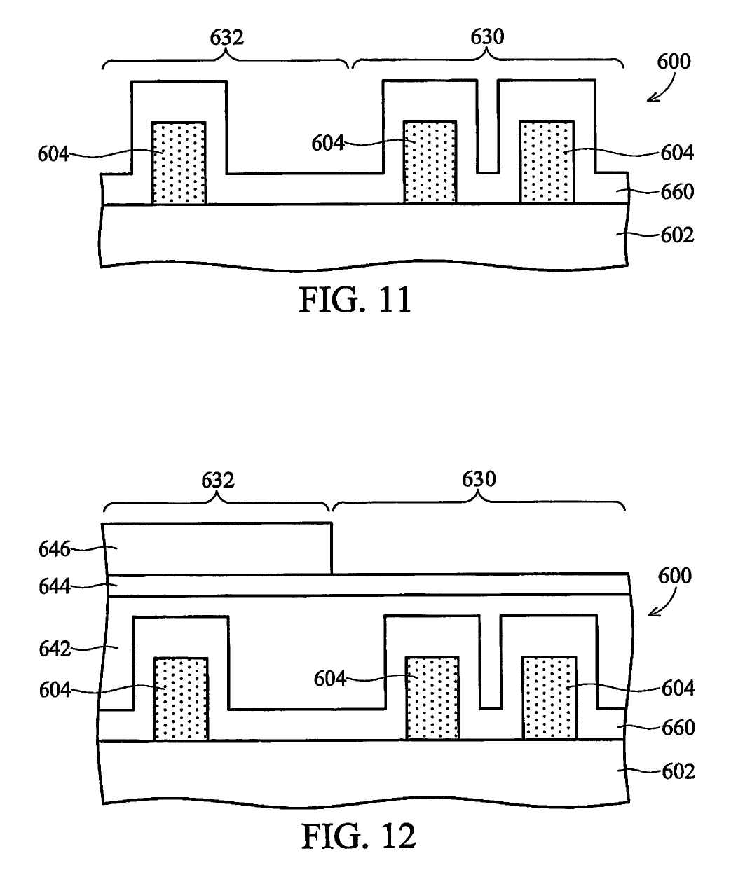

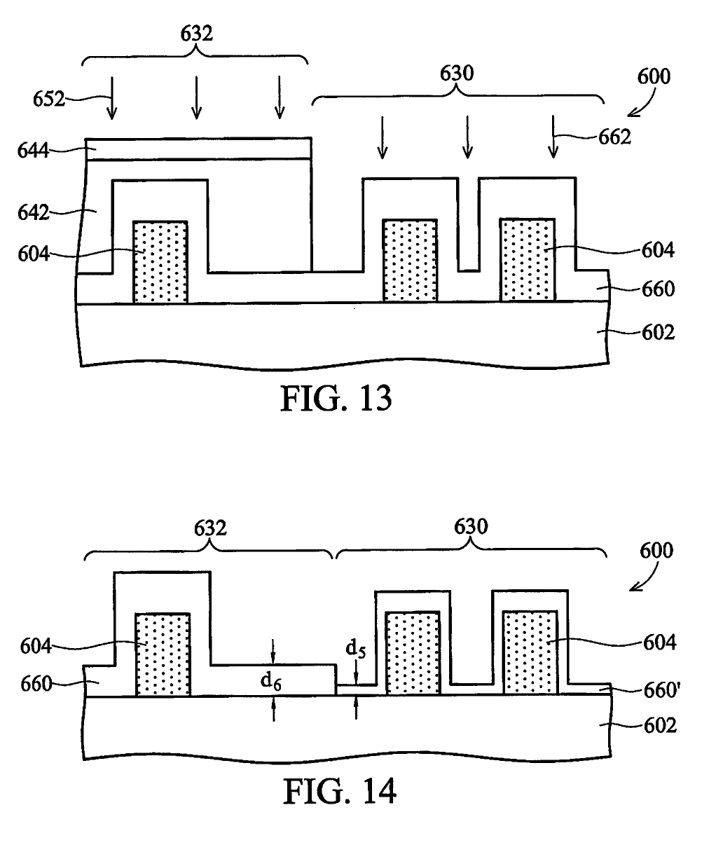

The first thickness d₅ and the at least one second thickness d₆ of the etch stop layer 428 may be formed by depositing a thin etch stop material over all of the features 404, and depositing an additional layer of etch stop material over only features in one region 430 or 432, to be described in further detail herein with reference to FIGS. 5 through 9. Alternatively, a thick layer of etch stop material may be deposited over all of the features 404, and a portion of the etch stop material may be removed from one region 430 or 432 of the workpiece 402, to be described further herein with reference to FIGS. 11 through 14.

Referring next to FIGS. 5 through 10, a semiconductor device 500 at various stages of manufacturing is illustrated in a cross-sectional view, in accordance with a preferred method of the present invention. The manufacturing steps demonstrate one method of achieving the etch stop layer 428 having two thicknesses shown in FIG. 4. Again, like numerals are used in FIGS. 5 through 10 as were used in the previous figures, and each element is not described in detail again herein. The etch stop material layers 540 and 544 shown in FIGS. 5 through 10 preferably comprise the same materials and thicknesses as were described for etch stop layers 106, 208, 306, 308, and 428 in the previous figures, for example.

In this embodiment, forming the etch stop layer 540/550 comprises forming a first material layer 540 over the workpiece in the first region 530 and the second region 532, and forming a second material layer 550 over the first material layer 540 in the second region 532. The first material layer 540 preferably comprises a thickness of about 10 to 60 nm in one embodiment. In particular, preferably, after the first material layer 540 is formed over the top surface of the workpiece 502 and the sidewalls and top surfaces of features 504 in both the first region 530 and the second region 532 as shown in FIG. 5, a protective material layer 542 is formed over the first region 530 of the workpiece 502, as shown in FIGS. 6 through 8. The second material layer 550 is deposited over the first material layer 540 in the second region 532 and over the protective material layer 542 in the first region 530, as shown in FIG. 9. The protective material layer 542 and the second material layer 550 are then removed from over the first region 530 of the workpiece 502, as shown in FIG. 10. Thus, the etch stop layer 540/550 comprises a first thickness d₅ in the first region 530 and a second thickness d₆ in the second region 532 of the workpiece 502.

Referring again to FIG. 6, the protective material layer 542 preferably comprises amorphous carbon. For example, the protective material layer 542 may be deposited by depositing a layer comprising a high percentage of carbon and hydrogen by chemical vapor deposition. The protective material layer 542 may comprise a thickness of about 300 nm or less, for example, and in one embodiment preferably comprises a thickness of about 80 nm to about 300 nm. The protective material layer 542 may alternatively comprise other materials and dimensions, for example.

The protective material layer 542 is preferably used to prevent the formation of the second material layer 550 over features 504 in the first region 530. The protective material layer 542 is sacrificially removed after the second material layer 550 is formed in the second region 532 of the workpiece. The second material layer 550 is simultaneously removed with the removal of the protective material layer 542, for example.

Other optional material layers may be used to facilitate the removal of the second material layer 550 in the first region 530. For example, an optional hard mask 544 and layer of photoresist 546 may be formed over the amorphous carbon layer 542, to be described next herein. After a blanket layer of protective material layer 542 comprising amorphous carbon is deposited, a hard mask 544 is formed over the amorphous carbon, as shown in FIG. 6. The hard mask 544 may comprise an oxide, a nitride, an oxynitride, or SiC having a thickness of about 10 nm to about 100 nm, as examples, although alternatively, the hard mask 544 may comprise other materials and dimensions. A layer of photoresist 546 is then deposited over the hard mask 544, and the layer of photoresist 546 is patterned (e.g., by an exposure and development process) to remove the layer of photoresist 546 from over the second region 532, as shown in FIG. 7. The layer of photoresist 546 is then used as a mask to pattern the hard mask 544 and the blanket layer of amorphous carbon 542, e.g., using an etch process, removing the blanket layer of amorphous carbon 542 and the hard mask 544 from over the second region 532 of the workpiece 502, as shown in FIG. 8. The layer of photoresist 546 is then removed from over the first region 530 of the workpiece 502, as shown in FIG. 9, and the second material layer 550 is deposited over the hard mask 544 in the first region 530 and over the first material layer 550 in the second region 532, also shown in FIG. 9.

Next, the amorphous carbon 542, the hard mask 544, and the second material layer 550 are removed from over the first region 530, as shown in FIG. 10, preferably using a removal process 552 (see FIG. 9) comprising an ash process or other process that sacrificially removes the amorphous carbon 542. For example, the removal process 552 for the amorphous carbon 542 preferably comprises ashing the amorphous carbon using O₂ plasma, a wet cleaning process comprised of H₂SO₄ and H₂O₂ (e.g., a “piranha” etch), or a wet process using dionized water (DI)/O₃. Because the removal process 552 removes the amorphous carbon 542, advantageously, the hard mask 544 and the second material layer 550 are both also removed from over the first region 530 of the workpiece 502, leaving the structure shown in FIG. 10.

FIGS. 11 through 14 illustrate a semiconductor device at various stages of manufacturing in accordance with another preferred method of the present invention. The manufacturing steps demonstrate another method of achieving the etch stop layer 428 having two thicknesses shown in FIG. 4. Again, like numerals are used in FIGS. 11 through 14 as were used in the previous figures, and each element is not described in detail again herein. The etch stop material layer 660 shown in FIGS. 11 through 14 preferably comprises the same materials and thicknesses as were described for etch stop layers 106, 208, 306, 308, 428, and 540/550 in the previous figures, for example.

In this embodiment, after the features 604 are formed in the first region 630 and the second region 632, a thick etch stop layer 660 is deposited over the entire workpiece 602, as shown in FIG. 11. Next, a protective material layer 642 is deposited over the entire workpiece 602 (FIG. 12) and removed from the first region (FIG. 13). An etch process 662 is used to thin the etch stop layer 660, removing a top portion of the etch stop layer 660 in the first region 630. The protective material layer 642 is then removed, as shown in FIG. 14, leaving a thicker etch stop layer 660 in the second region 632 having a second thickness d₆ and a thinner etch stop layer 660′ in the first region 630 having a first thickness d₅.

In this embodiment, an optional hard mask 644 and optional layer of photoresist 646 may be used to facilitate the formation of an etch stop layer 660 having different thicknesses in the first region 630 and second region 632 of the workpiece. The hard mask 644 may comprise similar materials and thicknesses as were described for the hard mask 544 shown in FIGS. 5 through 10, for example, although alternatively, other materials having other dimensions may also be used.

For example, referring to FIG. 12, after the amorphous carbon 642 is deposited, an optional hard mask 644 may be formed over the amorphous carbon 642, and a layer of photoresist 646 is then deposited over the hard mask 644. The layer of photoresist 646 is patterned (e.g., by an exposure and development process) to remove the layer of photoresist 646 from over the first region 632, as shown in FIG. 12. The layer of photoresist 646 is then used as a mask to pattern the hard mask 644 and the amorphous carbon 642, e.g., using an etch process, removing the amorphous carbon 642 and the hard mask 644 from over the first region 632 of the workpiece 602. The layer of photoresist 646 is then removed from over the second region 630 of the workpiece 602, as shown in FIG. 13.

The etch stop layer 660 is exposed to an etch process 662 to remove a top portion of the etch stop layer 660 in the first region 630, as shown in FIG. 13. For example, if the etch stop layer 660 comprises a nitride, a hot H₂PO₄ bath (e.g., a wet etch) may be used to reduce the etch stop layer 660 thickness, for about 1 to 15 minutes, which may vary depending on the concentration of the H₂PO₄, and the temperature and thickness of the etch stop layer 660, as examples. A dry etch using NF₃, SF₆, CF₄, or CHF₃ for a time period of about 20 seconds to 60 seconds may also be used, for example. Alternatively, the etch stop layer 660 may be reduced in thickness in the first region 630 using other material layer reduction methods, for example.

Next, the amorphous carbon 642 and the hard mask 644 are removed from over the second region 632, also shown in FIG. 13, preferably using a removal process 652 or other process that sacrificially removes the amorphous carbon 642. The removal process 652 preferably comprises a similar removal process as previously described with reference to removal process 552 shown in FIG. 9, for example. Because the etch process 652 removes the amorphous carbon 642, advantageously, the hard mask 644 is also removed from over the second region 632 of the workpiece 602, leaving the structure shown in FIG. 14.

Note that combinations of the features of the embodiments described herein may be implemented. For example, the etch stop materials 540, 550, and 660 of FIGS. 5 through 14 may comprise a poor step coverage as deposited, resulting in a thicker material being formed over top surfaces than sidewall surfaces. Likewise, the etch stop materials 540, 550, and 660 may have a high amount of stress, as described with reference to the embodiments shown in FIGS. 1 through 3.

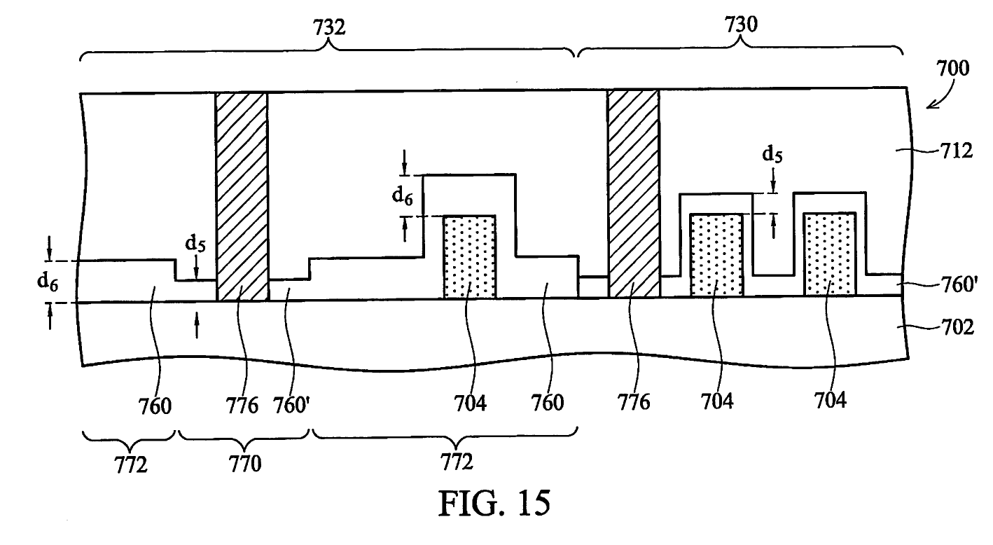

FIG. 15 shows a cross-sectional view of yet another preferred embodiment of the present invention, where the etch stop layer 760 over the top surface of portions 770 of the workpiece 702 has a reduced thickness. As in the previously described embodiments, again, like numerals are used in FIG. 15 as were used in the previous figures. This embodiment is advantageous if it is desired to have a single mask layer for forming contacts or vias 776 in the first and second regions 730 and 732, respectively, and/or if it is important not to expose the workpiece 702 for an excessive amount of time to the etch process to form the holes for the contacts or vias 772 in the insulating material 712, for example.

The methods described with reference to FIGS. 5 through 10 or FIG. 11 through 14 may be used to manufacture the embodiment shown in FIG. 15, for example. When the layer of photoresist 546 or 646 is patterned, portions 770 of the second region 732 are treated with the same process flow (e.g., using the same mask level) as the first region 730 of the workpiece 702, to form the thinner etch stop layer 760′ in those portions 770 of the second region 732. Other portions 772 of the workpiece 702 second region 732 where a thicker etch stop layer 760 is desired are treated with the process flow described for second regions 532 and 632 of the previous embodiments, for example.

Embodiments of the present invention include manufacturing methods to form the etch stop layers 106, 208, 306, 308, 428, 540/550, 660/660′, 760/760′ described herein having a different thickness in regions of the workpiece and/or having a high amount of stress. Embodiments of the present invention also include semiconductor devices 100, 200, 300, 400, 500, 600, 700 manufactured in accordance with the methods described herein, for example.

Embodiments of the present invention further include etch stop layer comprising one or more material layers. For example, each of the etch stop layers 106, 208, 306, 308, 428, 540/550, 660/660′, 760/760′ described herein may comprise one or more material layers, e.g., two material layers or greater. The multi-layer etch stop layers 106, 208, 306, 308, 428, 540/550, 660/660′, 760/760′ may comprise the same or different types of materials, for example.

Advantages of embodiments of the present invention include providing etch stop layers 106, 208, 306, 308, 428, 540/550, 660/660′, 760/760′ that are thicker in some regions and thinner in other regions, and/or have a high amount of stress. The yield of semiconductor devices 100, 200, 300, 400, 500, 600, 700 may be increased by the use of embodiments of the present invention. The etch stop layers 106, 208, 306, 308, 428, 540/550, 660/660′, 760/760′ may be used to create stress in the channel of an underlying transistor, in some embodiments. In one embodiment, shown in FIG. 3, the etch stop layer 306/308 comprises the same material as the sidewall spacer 310, preventing contact etch punch-through.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a workpiece, the workpiece comprising a first region and a second region; and
an etch stop layer disposed over the workpiece, wherein the etch stop layer comprises a first thickness in the first region and at least one second thickness in the second region, wherein the at least one second thickness is greater than the first thickness.

2. The semiconductor device according to claim 1, wherein the first region comprises a sidewall, and wherein the second region comprises a top surface.

3. The semiconductor device according to claim 1, wherein the first region comprises a closely-spaced feature region and wherein the second region comprises a widely-spaced feature region.

4. The semiconductor device according to claim 3, wherein features in the widely-spaced feature region are spaced apart from one another by about 2 to 5 times or more than features in the closely-spaced feature region are spaced apart from one another.

5. The semiconductor device according to claim 3, wherein the closely-spaced feature region comprises features that operate at a first speed, wherein the widely-spaced feature region comprises features that operate at a second speed, the first speed being greater than the second speed.

6. The semiconductor device according to claim 3, wherein the closely-spaced feature region comprises a plurality of memory cells, and wherein the widely-spaced feature region comprises logic and/or peripheral circuitry.

7. The semiconductor device according to claim 6, wherein the plurality of memory cells comprise static random access memory (SRAM) cells or dynamic random access memory (DRAM) cells.

8. The semiconductor device according to claim 1, wherein the first thickness and the at least one second thickness comprise a thickness of about 100 nm or less.

9. The semiconductor device according to claim 1, wherein the first thickness comprises a thickness of about 10 nm to about 60 nm, and wherein the at least one second thickness comprises a thickness of about 10 nm to about 60 nm.

10. The semiconductor device according to claim 1, wherein the at least one second thickness is about 200 nm or more greater than the first thickness.

11. The semiconductor device according to claim 1, wherein the first thickness is about 70% or less than the at least one second thickness.

12. The semiconductor device according to claim 1, wherein the etch stop layer comprises a tensile stress of about 0.8 GPa or greater, or a compressive stress of about −1.0 GPa or less.

13. The semiconductor device according to claim 1, wherein the etch stop layer comprises SiN, a nitride-containing material, SiON, SiC, or carbon-doped CVD oxide.

14. The semiconductor device according to claim 1, wherein the workpiece comprises a workpiece having at least one feature formed thereon, wherein the first region of the workpiece comprises a sidewall of the at least one feature, and wherein the second region of the workpiece comprises a top surface of the at least one feature and a top surface of at least a portion of the workpiece.

15. The semiconductor device according to claim 14, further comprising an insulating material disposed over the etch stop layer, and a contact disposed within the insulating material and the etch stop layer, wherein the contact makes electrical contact with the top surface of the at least one feature or the top surface of the at least a portion of the workpiece.

16. The semiconductor device according to claim 15, wherein the top surface of the workpiece comprises a first portion and a second portion, wherein the second region further comprises the first portion of the top surface of the workpiece, and wherein the first region further comprises the second portion of the top surface of the workpiece.

17. The semiconductor device according to claim 16, further comprising an insulating material disposed over the etch stop layer, and a contact disposed within the insulating material and the etch stop layer, wherein the contact make electrical contact with the at least one feature, the first portion of the top surface of the workpiece, or the first portion of the top surface of the workpiece.

18. A method of manufacturing the semiconductor device according to claim 1.

19. The semiconductor device according to claim 1, wherein the workpiece comprises a plurality of features formed thereon, wherein the pitch of the features comprises about 300 nm or less.

20. The semiconductor device according to claim 1, wherein the workpiece has at least one feature formed thereon, wherein the at least one feature comprises polysilicon or metal.

21. The semiconductor device according to claim 1, wherein the etch stop layer comprises one or more material layers.

22. A semiconductor device, comprising:
a workpiece; and
an etch stop layer over the workpiece, wherein the etch stop layer comprises a tensile stress of about 0.8 GPa or greater, or a compressive stress of about −1.0 GPa or less.

23. The semiconductor device according to claim 22, wherein the workpiece comprises a first region and a second region, wherein the etch stop layer comprises a first thickness in the first region and at least one second thickness in the second region, wherein the at least one second thickness is greater than the first thickness.

24. The semiconductor device according to claim 23, wherein the first region comprises a sidewall, and wherein the second region comprises a top surface.

25. The semiconductor device according to claim 23, wherein the first region comprises a closely-spaced feature region and wherein the second region comprises a widely-spaced feature region.

26. The semiconductor device according to claim 22, wherein the etch stop layer comprises SiN, a nitride-containing material, SiON, SiC, or carbon-doped oxide.

27. The semiconductor device according to claim 22, wherein the workpiece comprises at least one gate formed thereon, the at least one gate being disposed over a channel of a transistor, wherein the etch stop layer increases the stress of the channel of the transistor.

28. The semiconductor device according to claim 27, wherein the at least one gate comprises sidewalls, further comprising a spacer disposed on the sidewalls of the at least one gate.

29. The semiconductor device according to claim 28, wherein the etch stop layer comprises a first material, and wherein the spacer comprises the first material.

30. The semiconductor device according to claim 29, wherein the first material comprises a nitride material.

31. A method of manufacturing the semiconductor device according to claim 22.
